(19) United States
(12) Patent Application Publication
(10) Pub. No.: US 2026/0136968 A1
(43) Pub. Date: May 14, 2026

(54) HYBRID LAYERS IN SUBSTRATES

(71) Applicant: Micron Technology, Inc., Boise, ID (US)

(72) Inventors: Kimball D. Lowry, Boise, ID (US); Bradley R. Bitz, Meridian, ID (US); Travis M. Jensen, Boise, ID (US); Joao E. Chaves, Middleton, ID (US); David L. Christianson, Meridian, ID (US)

(21) Appl. No.: 19/380,705

(22) Filed: Nov. 5, 2025

Related U.S. Application Data
(60) Provisional application No. 63/718,336, filed on Nov. 8, 2024.

(51) Int. Cl. H01L 23/498

(52) U.S. Cl. CPC H10W 70/65; H10W 70/685; H10W 70/69

(57) ABSTRACT

Substrates and methods to manufacture such substrates are described. A substrate may be formed to include multiple metallic layers and multiple insulative layers, where each insulative layer is positioned between a respective pair of metallic layers. In some examples, one or more of insulative materials may be formed to include a first insulative material patterned with one or more portions of a first material, such as a third metal material or a second insulative material. In some other examples, the one or more insulative materials may be formed to include a pattern of one or more voids within a first insulative material of a hybrid layer. The substrate may be coupled with an integrated circuit, such as a memory device, of a semiconductor package.

### CROSS REFERENCE

The present Application for Patent claims priority to U.S. Patent Application No. 63/718,336 by Lowry et al., entitled “HYBRID LAYERS IN SUBSTRATES,” filed Nov. 8, 2024, which is assigned to the assignee hereof, and which is expressly incorporated by reference in its entirety herein.

### TECHNICAL FIELD

The following relates to substrates and methods to manufacture such substrates, including hybrid layers in substrates.

### BACKGROUND

A substrate may be a solid base material on which circuit components, such as integrated circuits, are mounted and electrically interconnected. A Printed Circuit Board (PCB) may be a type of substrate that provides a physical and electrical interface for such circuit components. A substrate, including a PCB (e.g., package substrates), may be utilized in memory applications, where memory devices, such as Random Access Memory (RAM), Read-Only Memory (ROM), and Not-AND (NAND) flash memory, may be coupled with the substrate for support during manufacturing or be utilized to couple (e.g., mount, solder, fuse) memory devices with or communication with host systems, such as computers, servers, and embedded systems.

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell of a memory device may support more than two states, any one of which may be stored by the memory cell. To store information, a memory device may write (e.g., program, set, assign) one or more states to the memory cells. To access stored information, a memory device may read (e.g., sense, detect, retrieve, determine) one or more states from the memory cells.

### BRIEF DESCRIPTION OF THE DRAWINGS

FIG. 1 shows examples of substrates that support hybrid layers in substrates in accordance with examples as disclosed herein.

FIG. 2 shows an example of a substrate that supports hybrid layers in substrates in accordance with examples as disclosed herein.

FIG. 3 shows an example of a substrate that supports hybrid layers in substrates in accordance with examples as disclosed herein.

FIG. 4 shows an example of a substrate that supports hybrid layers in substrates in accordance with examples as disclosed herein.

FIG. 5 shows an example of a substrate that supports hybrid layers in substrates in accordance with examples as disclosed herein.

FIG. 6 shows an example of a substrate that supports hybrid layers in substrates in accordance with examples as disclosed herein.

FIG. 7 shows an example of a system that supports hybrid layers in substrates in accordance with examples as disclosed herein.

FIG. 8 shows a flowchart illustrating a method or methods that support hybrid layers in substrates in accordance with examples as disclosed herein.

### DETAILED DESCRIPTION

Some semiconductors (e.g., memory devices, integrated circuits, semiconductor packages) may utilize substrates (e.g., printed circuit boards (PCBs), and package substrates, among other examples) to provide electrical connections between various components of a semiconductor, and/or provide mechanical and structural support for the semiconductor, among other examples. For example, a substrate may include one or more metallic layers (e.g., copper layer) configured to provide the electrical connections between various components of a semiconductor. In some cases, to avoid shorts between such metallic layers, the substrate may include a respective insulative layer (e.g., fiberglass, dielectric material) between each metallic layer, thereby isolating each metallic layer. In some cases, however, the substrate may experience a variety of structural or electrical failures, for example, due to extreme heat or cold, a condensed layout of electrical components on or within the substrate (e.g., PCB), exposure to moisture, and/or mechanical stresses of components coupled with the substrate, among other factors. Thus, techniques may be desired to improve the reliability of substrates, thereby avoiding such structural and electrical failures.

In accordance with the techniques described herein, a substrate may be formed with one or more voids in one or more layers of the substrate. Accordingly, the one or more voids may be formed according to a pattern, such that the one or more voids may be utilized to improve convective airflow through the substrate (e.g., remove heat or cool the substrate), and/or operate as moisture trap, among other examples. Additionally, or alternatively, the one or more voids may be filled with a material to improve the structural integrity of the substrate, improve isolation between electrical components within the substrate, and/or improve heat dissipation, among other examples.

Accordingly, to obtain the voids in the insulative layers of a substrate, a first metallic layer may be formed and an insulative layer (e.g., hybrid layer) may be formed over the first metallic layer. Based on forming the insulative layer, the one or more voids may be patterned (e.g., etched, machined, lasered) into the insulative layer according to a pattern, where the pattern may be based on a purpose (e.g., design function) of the insulative layer (e.g., based on whether the voids are used to dissipate heat or provide structural support). After forming the one or more voids in the insulative layer, a second metallic layer may be formed over the insulative layer. In some examples, prior to the second metallic layer being formed over the insulative material, a material may be deposited into one or more of the one or more voids, thereby filling the voids with a material that may be used for structural support, heat dissipation, and/or electrical connection, among other examples.

Techniques for hybrid layers in substrates (e.g., PCBs, package substrates) may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by improving various aspects of substrates, for example, by improving heat dissipation, improving moisture venting, and/or improving the structural integrity of substrates, among other examples, which may extend the life of electronic devices and thereby reducing electronic waste, among other benefits.

Features of the disclosure are illustrated and described in the context of substrates. Features of the disclosure are further illustrated and described in the context of systems and flowcharts.

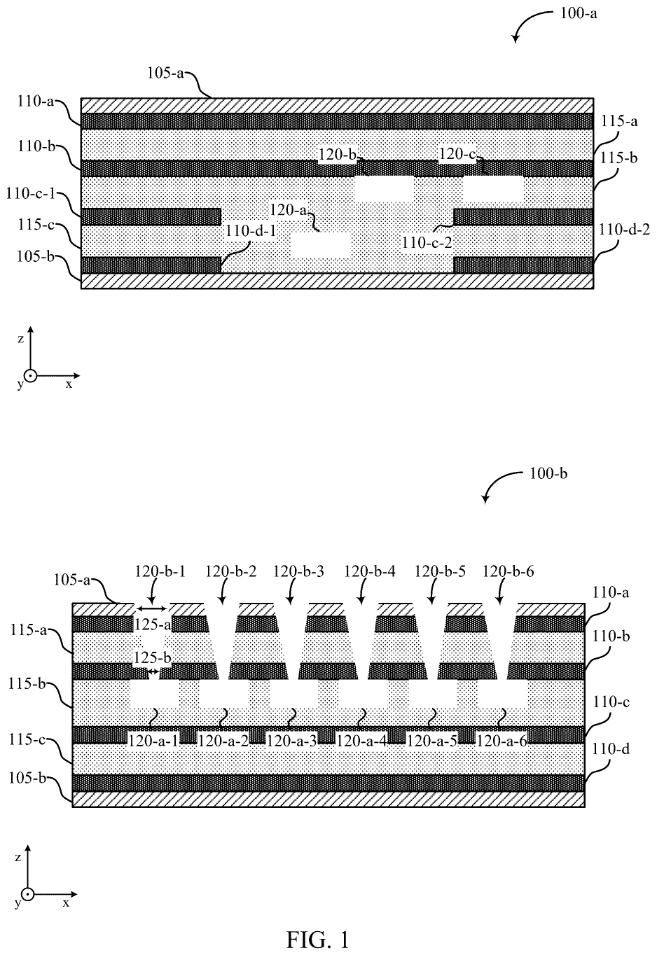

FIG. 1 shows examples of substrates 100 that support hybrid layers in substrates in accordance with examples as disclosed herein. The substrates 100 may be utilized during semiconductor manufacturing, may be coupled with one or more integrated circuits (e.g., be PCBs or package substrates), among other applications. The substrates 100 may be described in the context of an x-direction, y-direction, and a z-direction. Further, the techniques described in the context of the substrates 100 may enable the formation of one or more voids within the substrates 100.

Some semiconductors (e.g., memory devices, integrated circuits, semiconductor packages) may utilize the substrates 100 (e.g., PCBs) to provide electrical connections between various components of a semiconductor, and/or provide mechanical and structural support for the semiconductor, among other examples. At times, however, the substrate may experience a variety of structural or electrical failures during operation. In some cases, the substrates 100 may experience failure, reduced performance, or both (among other challenges) due to exposure to extreme heat. For example, during operation or during the manufacturing process, portions of the substrates 100 may experience increased heat (e.g., trap heat), which may compromise the integrity of the substrate, among other disadvantages.

In some cases, the substrates 100 may experience failure, reduced performance, or both due to mechanical stresses within the substrate. For example, a coefficient of thermal expansion (CTE) of the substrate may indicate how much the substrate might expand due to exposure to a variety of temperatures or during a temperature change, where different materials of the substrate may have respective CTE values that contribute to the overall CTE value of the substrate. Accordingly, the substrates 100 may experience mechanical (e.g., structural) failure during a temperature change due to the mismatch in CTE values of the variety of different materials in the substrates 100.

In some other cases, the substrates 100 may experience cross-talk (e.g., electromagnetic coupling) between two components (e.g., traces) of the substrates 100 during operation, thereby leading to reduced electrical performance, failure, or both. Additionally, or alternatively, the substrates 100 may experience reduced performance, failure, or both (among other challenges) due to exposure to moisture during operation or manufacturing. For example, the materials used to form the substrates 100 may absorb moisture during various stages of the manufacturing process, which may lead to failures during assembly of the substrate, among other examples.

In accordance with the techniques described herein, one or more layers of the substrates 100 may be altered to mitigate the structural or electrical failures. For example, the substrates 100 may include one or more insulative layers 115 (e.g., core layers, prepreg layers, glass weave, resins, fillers, dielectric materials), which may be used to isolate one or more metallic layers 110 (e.g., copper layers). Accordingly, to improve the functionality of the substrates 100 and reduce failures in the substrates 100, the insulative layers 115 may be modified by machining or etching according to a pattern, such that the pattern may be used as a mold to be filled with another material or left unfilled to create one or more voids 120 (e.g., open channels) within the insulative layers.

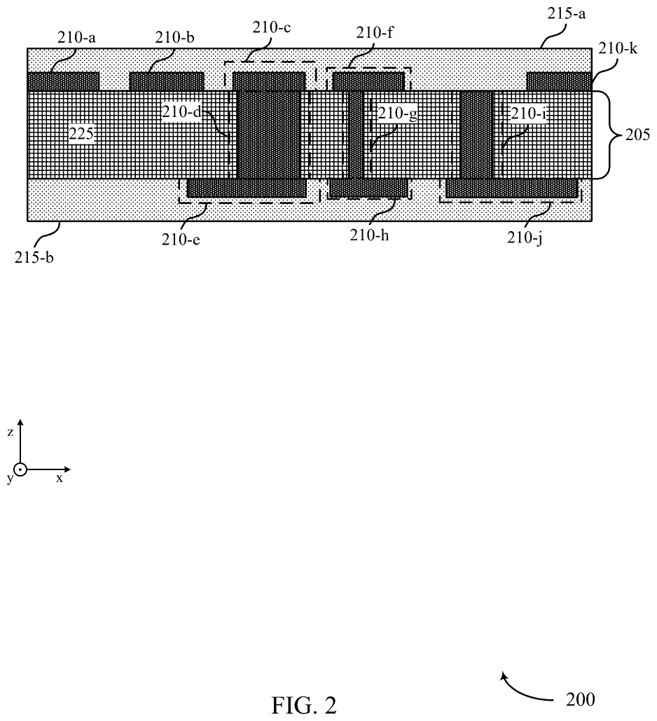

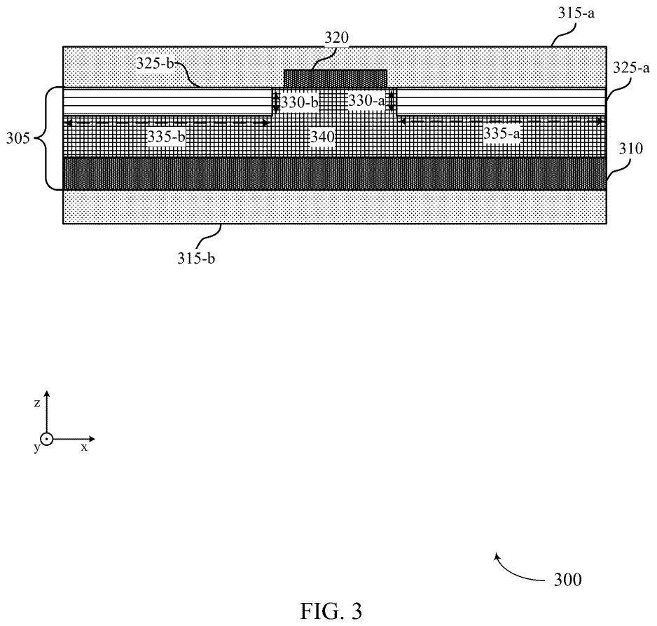

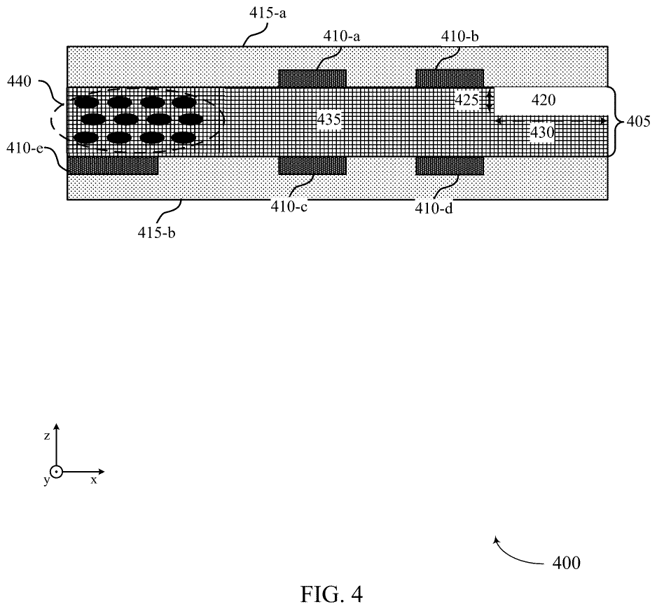

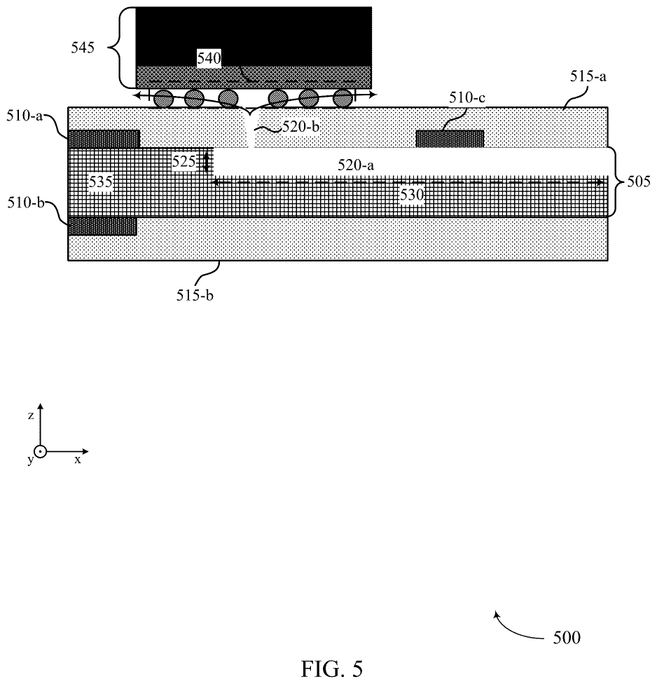

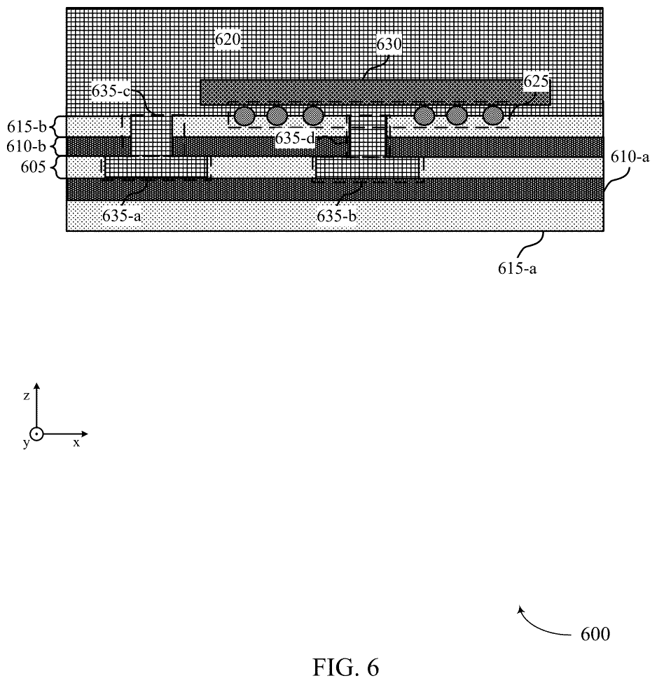

That is, one or more insulative layers 115 of the substrates 100 may be formed to include one or more voids 120, where such voids 120 may in some examples be filled with a material which may aid in heat extraction (e.g., as further described herein with reference to FIG. 3), reduce structural failures from mismatched CTE values (e.g., as further described herein with reference to FIG. 6), and/or improve electrical shielding (e.g., as further described herein with reference to FIG. 2), among other examples. Alternatively, the voids 120 may not be filled with a material, and instead be used to provide cooling such as convection cooling (e.g., as further described herein with reference to FIG. 5), utilized to trap (e.g., vent) moisture from within the substrates 100 (e.g., as further described herein with reference to FIG. 4), and/or be used as a vent for excess molding (e.g., as described herein with reference to FIG. 6).

In such examples, the voids 120 (e.g., voided pattern) may be extended to an edge (e.g., in the x-direction) of the substrates 100 (e.g., package or PCB), may be extended to a top or bottom (e.g., in the z-direction) of the substrates 100, or both. In some examples, in addition to, or as an alternative to the voids 120, the insulative layers 115 may include a porous material (e.g., as further described herein with reference to FIG. 4), which may facilitate the collection of moisture for wicking to the edge (e.g., in the x-direction) of the substrates 100 or facilitate airflow through the substrates 100.

To form the substrates 100, a layer manufacturing process may be utilized, where raw materials may be laminated (e.g., pressed) in sheet form. Accordingly, one or more of an etching process (e.g., dry or wet etch), machining process, or laser drilling process may be performed to form the patterned voids 120 within the insulative layers 115. Additionally, or alternatively, similar processes to wafer fabrication may be utilized to form the patterned voids 120 within the insulative layers 115. In some examples, in response to forming the voids 120, additional processing steps may be performed to deposit other materials into the voided pattern (e.g., liquid dispense and cure procedure, deposition and etch back).

In some examples, the voids 120 may be formed (e.g., laminated) using a sacrificial material that is removed post lamination. That is, the insulative layers 115 may be formed to include (e.g., combined with) one or more portions of a sacrificial material, where the one or more portions of the sacrificial material may be removed in response to a completion of a laminating process for the substrates 100, thereby forming the voids 120. For example, the removal of the sacrificial material may be performed during a post assembly reflow. In such examples, the sacrificial material may be soluble, such that the sacrificial material may be removed during a water bath of the substrates 100, in response to exposure to moisture content (e.g., saturation), or in response to exposure of a surfactant. In some examples, the sacrificial material may be removed according to a chemical activation, such as a photo resist process.

For example, the substrate 100-a may include a solder resist 105-a and a solder resist 105-b, which may be a top and bottom surface of the substrate 100-a. The substrate 100-a may also include one or more metallic layers 110 between the solder resists 105, such as the metallic layer 110-a, 110-b, 110-c, and 110-d. As described herein, to isolate the metallic layers 110 from each other, the substrate 100-a may include one or more insulative layers 115, such as the insulative layer 115-a, 115-b, and 115-c.

In some examples, an insulative layer 115 may extend into a second insulative layer 115, thereby separating a metallic layer 110 into one or more portions. For example, as illustrated, the insulative layer 115-b may extend through the metallic layer 110-c to the insulative layer 115-c, such that the metallic layer 110-c may include a first portion 110-c-1 of the metallic layer 110-c (e.g., a metallic pad) and a second portion 110-c-2 of the metallic layer 110-c. Similarly, the insulative layer 115-c may extend through the metallic layer 110-d to the solder resist 105-b, such that the metallic layer 110-d may include a first portion 110-d-1 of the metallic layer 110-d (e.g., a metallic pad) and a second portion 110-d-2 of the metallic layer 110-d. As described herein, one or more voids 120 may be formed into one or more insulative layers 115 of the substrate 100-a. For example, the insulative layer 115-c may include a void 120-a, while the insulative layer 115-b may include a void 120-b and a void 120-c. The insulative layers 115-a and 115-b may be referred to as a hybrid layer. That is, a hybrid layer may be a layer within the substrates 100 that includes one or more voids 120, is a layer that includes a first insulative material patterned with one or more portions of a different material, or a combination of both. Although not illustrated, in some examples, a border material (e.g., border layer) may be included along the edges of the voids 120 within the substrate 100-a.

To form the substrate 100-a, the metallic layer 110-d may be formed, where, an etching procedure may be performed to remove a portion of the metallic layer 110-d, thereby forming the portion 110-d-1 and the portion 110-d-2. In response, the insulative layer 115-c may be formed between the portion 110-d-1 and the portion 110-d-2 and over the portion 110-d-1 and the portion 110-d-2. Based on forming the insulative layer 115-c, the void 120-a may be formed (e.g., using the etching, machining, or laser drilling process). Alternatively, the insulative layer 115-c may be patterned with a sacrificial material at a position corresponding to the void 120-a, where such sacrificial material may be removed in response to completion of the substrate 100-a.

In response to forming the insulative layer 115-c, the metallic layer 110-c may be formed over the insulative layer 115-c (e.g., in the z-direction and along the x-direction), where, an etching procedure may be performed to remove a portion of the metallic layer 110-c, thereby forming the portion 110-c-1 and the portion 110-c-2. In response, the insulative layer 115-b may be formed between the portion 110-c-1 and the portion 110-c-2 and over the portion 110-c-1 and the portion 110-c-2. Based on forming the insulative layer 115-b, the voids 120-a and 120-c may be formed (e.g., using the etching, machining, or laser drilling process). Alternatively, the insulative layer 115-b may be patterned with a sacrificial material at a position corresponding to the voids 120-b and 120-c, where such sacrificial material may be removed in response to completion of the substrate 100-a.

In response to forming the insulative layer 115-b, the metallic layer 110-b may be formed over the insulative layer 115-b, the insulative layer 115-a may be formed over (e.g., in the z-direction and along the x-direction) the metallic layer 110-b, and the solder resist 105-a may be formed over (e.g., in the z-direction and along the x-direction) the metallic layer 110-a.

Similarly, the substrate 100-b may include a solder resist 105-a and a solder resist 105-b, which may be a top and bottom surface of the substrate 100-b. The substrate 100-b may also include one or more metallic layers 110 between the solder resists 105, such as the metallic layer 110-a, 110-b, 110-c, and 110-d. As described herein, to isolate the metallic layers 110 from each other, the substrate 100-b may include one or more insulative layers 115, such as the insulative layer 115-a, 115-b, and 115-c.

As described herein, one or more voids 120 may be formed into one or more insulative layers 115 of the substrate 100-a according to a pattern. For example, the insulative layer 115-b may include voids 120-a-1 through 120-a-6. Additionally, the substrate 100-b may include one or more additional voids 120 that extend through various layers to an edge (e.g., top) of the substrate 100-b. For example, as illustrated, the substrate 100-b may include the voids 120-b-1 through 120-b-6, where each void 120-b may extend from a respective void 120-a through the metallic layer 110-b, the insulative layer 115-a, the metallic layer 110-a, and the solder resist 105-a. In such examples, the combination of a void 120-a and a void 120-b may be referred to as a single void (e.g., vent, ducting, piping) and may be utilized for heat dissipation, among other uses. Although not illustrated, in some examples, a border material (e.g., border layer) may be included along the edges of the voids 120 within the substrate 100-b.

To form the substrate 100-b, the metallic layer 110-d may be formed over the solder resist 105-b. In response, the insulative layer 115-c may be formed over (e.g., in the z-direction and along the x-direction) the metallic layer 110-d. In response to forming the insulative layer 115-c, the metallic layer 110-c may be formed over the insulative layer 115-c (e.g., in the z-direction and along the x-direction). In response, the insulative layer 115-b may be formed over (e.g., in the z-direction and along the x-direction) the metallic layer 110-c. Based on forming the insulative layer 115-b, the voids 120-a may be formed (e.g., using the etching, machining, or laser drilling process). Alternatively, the insulative layer 115-b may be patterned with a sacrificial material at a position corresponding to the voids 120-a, where such sacrificial material may be removed in response to completion of the substrate 100-b.

In response to forming the insulative layer 115-b, the metallic layer 110-b may be formed over (e.g., in the z-direction and along the x-direction) the insulative layer 115-b, the insulative layer 115-a may be formed over (e.g., in the z-direction and along the x-direction) the metallic layer 110-b, and the solder resist 105-a may be formed over (e.g., in the z-direction and along the x-direction) the metallic layer 110-a. In response, the voids 120-b may be formed (e.g., using the etching, machining, mechanical drilling, or laser drilling process). For example, the portions of the solder resist 105-a, the metallic layer 110-a, the metallic layer 110-b, and the insulative layer 115-a may be removed to form the voids 120-b. In some examples, the voids 120-b may have a tapered structure (e.g., a distance 125-a at a top of the voids 120-b may be greater than a distance 125-b of a bottom of the voids 120-b) due to the process (e.g., the etching process, the machining process, the laser drilling process, or the mechanical drilling process) used to form the voids 120-b.

By implementing the voids 120 within the insulative layers 115 patterned with voids 120 or other materials (e.g., a hybrid layer), the substrates 100 may experience improved signal performance, heat management, moisture management, reduced failures related to heat, and improved structural integrity, thereby compensating for CTE mismatch in relatively high stress locations of the substrates 100.

FIG. 2 shows an example of a substrate 200 that supports hybrid layers in substrates in accordance with examples as disclosed herein. Aspects of the substrate 200 may implement, or be implemented by, aspects of the substrates 100, as described herein with reference to FIG. 1. For example, the substrate 200 may include an insulative layer 215-a and an insulative layer 215-b, which may be examples of insulative layers 115 as described herein. The substrate 200 may be described in the context of an x-direction, y-direction, and a z-direction. Further, the techniques described in the context of the substrate 200 may enable the formation of a hybrid layer 205 within the substrate 200, which may be utilized to shield between signal pads of the substrate 200.

The hybrid layer 205 of the substrate 200 may be positioned (e.g., in the z-direction) between the insulative layer 215-a and the insulative layer 215-b (e.g., prepreg layers, dielectric materials). In such examples, the hybrid layer 205 may include a core material 225 (e.g., a first insulative material, dielectric), which may be a same insulative material as those used for the insulative layers 215 or be a different insulative material from those used the insulative layers 215.

In some examples, the insulative layers 215 and the hybrid layer 205 may include one or more metallic pads 210. For example, the insulative layer 215-a may include a metallic pad 210-a (e.g., first signal pad), a metallic pad 210-b (e.g., second signal pad), a metallic pad 210-c (e.g., first power plane pad), a metallic pad 210-f (e.g., third signal pad), and a metallic pad 210-k (e.g., fourth signal pad). The insulative layer 215-b may include a metallic pad 210-e (e.g., second power plane pad), a metallic pad 210-h (e.g., fifth signal pad), and a metallic pad 210-j (e.g., a ground plane pad).

In such examples, to avoid cross-talk between the metallic pads 210 (e.g., signal pads) and improve referencing (among other advantages), the hybrid layer 205 may be formed with one or more metallic pads 210 that extend the metallic pads 210-e and 210-j (e.g., power and ground planes) between the insulative layer 215-a and insulative layer 215-b. For example, to mitigate the cross-talk between the metallic pads 210-b and 210-f (e.g., second and third signal pads), the hybrid layer 205 may include the metallic pad 210-d, which may couple the metallic pad 210-c with the metallic pad 210-e (e.g., extend the power plane). Similarly, to mitigate the cross-talk between the metallic pads 210-f and 210-k (e.g., third and fourth signal pads), the hybrid layer 205 may include the metallic pad 210-i, which may extend the metallic pad 210-j (e.g., the ground plane) from the insulative layer 215-b through the hybrid layer 205 and to the insulative layer 215-a. Additionally, in some examples, the hybrid layer 205 may be formed to include a metallic pad 210-g, which may couple the metallic pad 210-f (e.g., fourth signal pad) with the metallic pad 210-h (e.g., fifth signal pad).

To form the substrate 200, the insulative layer 215-b may be formed, where one or more portions of the insulative layer 215-b may be etched (e.g., removed) to form one or more cavities (e.g., three cavities). Accordingly, the metallic pads 210-e, 210-h, and 210-j may be formed within the one or more cavities (e.g., copper may be deposited within the cavities). In response, the insulative material of the hybrid layer 205 may be formed over (e.g., in the z-direction and extending along the x-direction) the insulative layer 215-b. The hybrid layer 205 may be patterned with one or more voids (e.g., three voids) according to a pattern. Accordingly, the metallic pads 210-d, 210-g, and 210-i may be formed within a respective void of the one or more voids (e.g., copper may be deposited in the voids). Based on forming the hybrid layer 205, the metallic pads 210-a, 210-b, 210-c, 210-f, and 210-k may be formed over the hybrid layer 205 and the insulative layer 215-a may be formed around the metallic pads 210-a, 210-b, 210-c, 210-f, and 210-k.

Accordingly, by allowing alternative materials to be used for shielding between the metallic pads 210 of the insulative layers 215-a, extending a referencing plane (e.g., power plane or ground plan) through the hybrid layer 205 into the insulative layer 215-a, or both, the electrical performance of the substrate 200 may be improved, among other advantages.

FIG. 3 shows an example of a substrate 300 that supports hybrid layers in substrates in accordance with examples as disclosed herein. Aspects of the substrate 300 may implement, or be implemented by, aspects of the substrates 100 and the substrate 200, as described herein with reference to FIGS. 1 and 2. For example, the substrate 300 may include an insulative layer 315a and an insulative layer 315b, which may be examples of insulative layers 115 and insulative layers 215 as described herein. Further the substrate 300 may include a metallic layer 310, which may be an example of the metallic layers 110 as described herein. The substrate 300 may be described in the context of an x-direction, y-direction, and a z-direction. Further, the techniques described in the context of the substrate 300 may enable the formation of a hybrid layer 305 within the substrate 300, which may be utilized for heat dissipation.

For example, the substrate 300 may include the insulative layer 315-b, the metallic layer 310 (e.g., power plane or ground plane) over the insulative layer 315-b (e.g., in the z-direction), the hybrid layer 305 over the metallic layer 310 (e.g., in the z-direction), and the insulative layer 315-a over the hybrid layer 305. In such examples, the insulative layer 315-a may include a metallic pad 320 (e.g., copper signal pad), which may be an example of the metallic pads 210. In some examples, instead of the insulative layer 315-a being over the hybrid layer 305, a second metallic layer (e.g., second power or ground plane) may be formed over the hybrid layer 305.

In such examples, the hybrid layer 305 may include a core material 340 (e.g., insulative material, dielectric material). Additionally, the hybrid layer may include a portion 325-a of a thermally conductive material at a first side of the hybrid layer (e.g., in the x-direction) and a portion 325-b of the thermally conductive material at a second side of the hybrid layer. In such examples, the thermally conductive material may have a higher thermal conductivity relative to that of the core material 340, such that the portions 325 may extract heat generated from the metallic layer 310 (e.g., ground or power plane) and the metallic pad 320 and function as an internal heat sink for the substrate 300. In some examples, the hybrid layer 305 may include one or more additional portions 325 of the thermally conductive material, where such additional portions 325 may be positioned on a top of the metallic layer 310, thereby enabling such additional portions 325 to further extract heat from the substrate 300.

To form the substrate 300, the insulative layer 315-b may be formed and the metallic layer 310 may be formed over the insulative layer 315-b. Based on forming the metallic layer 310, the hybrid layer 305 may be formed.

For example, the core material 340 (e.g., first insulative material) may be formed over the metallic layer 310. In response, a first void may be etched (e.g., wet etch, dry etch, machined, lasered) into the first side (e.g., right side in the x-direction) of the core material 340, where the first void may extend from a first edge of the core material 340 into the length 335-a of the core material 340 and extend from a top of the core material into the length 330-a of the core material 340. Similarly, a second void may be etched into the second side (e.g., left side in the x-direction) of the core material 340, where the second void may extend from a second edge of the core material 340 into the length 335-b of the core material 340 and extend from the top of the core material into the length 330-b of the core material 340.

In response to etching first and second voids, the portions 325 of the thermally conductive material may be formed in the first and second voids. For example, the portion 325-a may be formed in the first void, while the portion 325-b may be formed in the second void. Based on forming the hybrid layer 305, the metallic pad 320 may be formed over a portion of the core material 340 of the hybrid layer 305 and the insulative layer 315-a may be formed around the metallic pad 320 and over the hybrid layer 305.

Accordingly, by implementing the portions 325-b with increased thermal conductivity (e.g., superior heat conducting properties) in portions of the substrate 300 associated with relatively higher temperatures (e.g., near ground planes, power planes, concentrated signal pads), the portions 325 may serve as an internal heat sink, thereby dissipating heat from the substrate 300. Additionally, by implementing the portions 325-b (e.g., metallic material) in the substrate 300, the volume of metal within the substrate 300 may increase, thereby improving a capacitance of the substrate 300, among other advantages.

FIG. 4 shows an example of a substrate 400 that supports hybrid layers in substrates in accordance with examples as disclosed herein. Aspects of the substrate 400 may implement, or be implemented by, aspects of the substrates 100, the substrate 200, and the substrate 300, as described herein with reference to FIGS. 1 through 3. For example, the substrate 400 may include an insulative layer 415a and an insulative layer 415b, which may be examples of insulative layers 115, insulative layers 215, and insulative layers 315 as described herein. The substrate 400 may be described in the context of an x-direction, y-direction, and a z-direction. Further, the techniques described in the context of the substrate 400 may enable the formation of a hybrid layer 405 within the substrate 400, which may be utilized as a moisture trap.

For example, the substrate 400 may include the insulative layer 415-a over (e.g., in the z-direction) the hybrid layer 405, where the hybrid layer 405 may be over (e.g., in the z-direction) the insulative layer 415-b. The insulative layer 415-a may include one or more metallic pads 410 (e.g., copper signal pads), such as the metallic pad 410-a and the metallic pad 410-b. As illustrated, the metallic pads 410-a and 410-b may be in contact (e.g., coupled or touching) the hybrid layer 405. Similarly, the insulative layer 415-b may include one or more metallic pads 410, such as the metallic pad 410-c, the metallic pad 410-d, and the metallic pad 410-e. As illustrated, the metallic pads 410-c, 410-d, and 410-e may be in contact (e.g., coupled or touching) the hybrid layer 405 of the substrate 400.

The hybrid layer 405 may include a core material 435 and one or more voids 420. In such examples, the core material 435 may be a porous material, such as hollow glass strands, a soluble resin, a sintered porous plastic, porous fiber, a polytetrafluoroethylene membrane, and/or a glass weave, among other examples. Such core material 435 (e.g., porous material) may enable the hybrid layer 405 to function as a moisture trap, where moisture 440 may collect in the core material 435 via organic saturation and be vented to an edge of the substrate 400 to control out-gassing.

In such examples, to facilitate the control of out-gassing, hybrid layer 405 may include a void 420 at an edge of the substrate (e.g., at the right of the substrate 400 in the x-direction), which may extend (e.g., in the x-direction) from the edge of the substrate 400 into the core material 435 by a length 430 and extend (e.g., in the y-direction) from a top of the hybrid layer 405 (e.g., a bottom of the insulative layer 415a) into the core material 435 by a length 425. In some examples, the substrate may include a second void 420 at a second edge opposite the first edge of the substrate 400 (e.g., at a left side of the substrate 400 in the x-direction). Such voids 420 may collect the moisture 440 absorbed by the core material 435 to control out-gassing, where the trapped moisture would have a vent for liquid to gas phase changes. Although not illustrated, in some examples, a border material (e.g., border layer) may be included along the edges of the void 420 within the substrate 400.

To form the substrate 400, the insulative layer 415-b may be formed and one or more cavities may be etched into the insulative layer 415-b. Based on etching the one or more cavities, a metallic material (e.g., copper) may be deposited into each of the one or more cavities to form the metallic pads 410-c, 410-d, and 410-e. Based on forming the insulative layer 415-b, the hybrid layer 405 may be formed.

For example, the core material 435 may be formed over the insulative layer 415-b. In response, the void 420 may be etched (e.g., wet etch, dry etch, machined, lasered) into a first side (e.g., right side in the x-direction) of the core material 435, where the void 420 may extend from the edge of the core material 435 into the length 430 of the core material 435 and extend from a top of the core material 435 into the length 425 of the core material 435. Based on forming the hybrid layer 405, the metallic pads 410-a and 410-b may be formed over the hybrid layer 405 and the insulative layer 415-a may be formed around the metallic pads 410-a and 410-b and over the hybrid layer 405. In some examples, instead of forming the void 420 prior to the formation of the metallic pads 410-a and 410-b and the insulative layer 415-a, the void 420 may be formed in response to the formation of the metallic pads 410-a and 410-b and the insulative layer 415-a.

For example, the core material 435 may be formed over the insulative layer 415-b and the metallic pads 410-c, 410-d, and 410-e, the metallic pads 410-a and 410-b may be formed over the core material 435, and the insulative layer 415-a may be formed around the metallic pads 410-a and 410-b and over the core material 435. In response, the void 420 may be etched into the core material 435 using any one of a machining, laser etching, wet etch, or dry etch procedure. In some other examples, the core material 435 may be patterned with a sacrificial material, where the sacrificial material may be removed after formation of the substrate 400 thereby forming the void 420.

Accordingly, by implementing the void 420 and the porous core material 435 into the substrate 400 (e.g., the voided pattern), the hybrid layer 405 may be utilized as a moisture trap, thereby allowing moisture 440 to vent out, which may be improve adhesion, reduce out-gassing delamination issues, reduce additional heat steps during manufacture, improve material integrity, among other advantages.

FIG. 5 shows an example of a substrate 500 that supports hybrid layers in substrates in accordance with examples as disclosed herein. Aspects of the substrate 500 may implement, or be implemented by, aspects of the substrates 100, the substrate 200, the substrate 300, and the substrate 400, as described herein with reference to FIGS. 1 through 4. For example, the substrate 500 may include an insulative layer 515a and an insulative layer 515b, which may be examples of insulative layers 115, insulative layers 215, insulative layers 315, and insulative layers 415 as described herein. The substrate 500 may be described in the context of an x-direction, y-direction, and a z-direction. Further, the techniques described in the context of the substrate 500 may enable the formation of a hybrid layer 505 within the substrate 500, which may be utilized as an air vent.

The substrate 500 may include the insulative layer 515-b, which may include one or more metallic pads 510 (e.g., copper signal pads), such as the metallic pad 510-b. The substrate 500 may also include the hybrid layer 505 over (e.g., in the z-direction) the insulative layer 515-b, where the hybrid layer 505 may include a core material 535 (e.g., first insulative material, dielectric) and one or more voids 520. For example, the hybrid layer 505 may include a void 520-a, which may extend (e.g., in the z-direction) from a top of the core material 535 into the core material 535 by a length 525 and extend (e.g., in the x-direction) from an edge of the substrate 500 (e.g., the right side of the substrate 500 in the x-direction) into the core material 535 by a length 530.

The substrate 500 may also include the insulative layer 515-a, which may include one or more metallic pads 510, such as the metallic pads 510-a and 510-c, and also include one or more voids 520, such as the void 520-b. That is, the insulative layer 515-a may include the void 520-b, which may extend (e.g., in the z-direction) from the void 520-a to a top of the insulative layer 515-a (e.g., extend through the insulative layer 515-a). The substrate 500 may also include multiple metallic pads 540 (e.g., solder balls, copper solder joints, ball grid arrays (BGAs)), where a first set of the metallic pads 540 may be formed on a first side (e.g., right side in the x-direction) of the void 520-b and a second set of the metallic pads 540 may be formed on a second side (e.g., left side in the x-direction) of the void 520-b. As illustrated, the substrate 500 may be coupled with an integrated circuit 545 via the metallic pads 540, where the integrated circuit 545 may be a memory device, a component of a memory device, a flip chip, or another semiconductor device.

As described herein, the voids 520-a and 520-b may be combined to form a single void 520, which may be a convective vent to facilitate airflow from the integrated circuit 545, facilitate airflow to the integrated circuit 545, or both. Such a convective vent may be created via a Venturi effect, where metal density of the substrate 500 may drive a heat sink like flow or provide a high to low pressure differential. For example, the voids 520 may be an air channel that is directly under the metallic pads 540 (e.g., BGA components, which may enable air to flow through an edge of the substrate 500. In this way, airflow may be introduced between the metallic pads 540 and the substrate 500, thereby pulling heat out of the solder joints and the surrounding circuitry (e.g., integrated circuit 545). Although not illustrated, in some examples, a border material (e.g., border layer) may be included along the edges of the voids 520 within the substrate 500.

To form the substrate 500, the insulative layer 515-b may be formed and one or more cavities may be etched into the insulative layer 515-b. Based on etching the one or more cavities, a metallic material (e.g., copper) may be deposited into each of the one or more cavities to form the metallic pad 510-b. Based on forming the insulative layer 515-b, the hybrid layer 505 may be formed.

For example, the core material 535 may be formed over the insulative layer 515-b. In response, the void 520-a may be etched (e.g., wet etch, dry etch, machined, lasered) into a first side (e.g., right side in the x-direction) of the core material 535, where the void 520-a may extend from the edge of the core material 535 into the length 530 of the core material 535 and extend from a top of the core material 535 into the length 525 of the core material 535. Based on forming the hybrid layer 505, the metallic pads 510-a and 510-c may be formed over the hybrid layer 505 and the insulative layer 515-a may be formed around the metallic pads 510-a and 510-c and over the hybrid layer 505. Based on forming the insulative layer 515-a, the void 520-b may be etched through the insulative layer 515-a, where the metallic pads 540 may then be formed over the insulative layer 515-a.

In some examples, instead of forming the void 520-a prior to the formation of the metallic pads 510-a and 510-c and the insulative layer 515-a, the void 520-a may be formed in response to the formation of the metallic pads 510-a and 510-c and the insulative layer 515-a.

For example, the core material 535 may be formed over the insulative layer 515-b, the metallic pads 510-a and 510-c may be formed over the core material 535, and the insulative layer 515-a may be formed around the metallic pads 510-a and 510-c and over the core material 535. In response, the void 520-a may be etched into the core material 535 using any one of a machining, laser etching, wet etch, or dry etch procedure. In some other examples, the core material 535 and the insulative layer 515-a may be patterned with a sacrificial material, where the sacrificial material may be removed after formation of the substrate 500 thereby forming the voids 520.

Accordingly, by implementing the voids 520 into the substrate 500 (e.g., the voided pattern), the hybrid layer 505 may be utilized to facilitate air flow to and from integrated circuits 545 coupled with the substrate 500, thereby colling such integrated circuits 545, which may prevent overheating, among other advantages.

FIG. 6 shows an example of a substrate 600 that supports hybrid layers in substrates in accordance with examples as disclosed herein. Aspects of the substrate 600 may implement, or be implemented by, aspects of the substrates 100, the substrate 200, the substrate 300, the substrate 400, and the substrate 500, as described herein with reference to FIGS. 1 through 5. For example, the substrate 600 may include an insulative layer 615a and an insulative layer 615b, which may be examples of insulative layers 115, insulative layers 215, insulative layers 315, insulative layers 415, and insulative layers 515 as described herein. Similarly, the substrate 600 may include a metallic layer 610a and a metallic layer 610b, which may be examples of the metallic layers 110 as described herein. The substrate 600 may be described in the context of an x-direction, y-direction, and a z-direction. Further, the techniques described in the context of the substrate 600 may enable the formation of a hybrid layer 605 within the substrate 600, which may be utilized to reduce mechanical stress and act as a vent for molding material 620.

The substrate 600 may include alternating metallic and insulative layers. For example, the substrate 600 may include the insulative layer 615-a, the metallic layer 610-a over (e.g., in the z-direction) the insulative layer 615-a, the hybrid layer 605 over the metallic layer 610-a, the metallic layer 610-b over the hybrid layer 605, and the insulative layer 615-b over the metallic layer 610-b. As illustrated, the substrate 600 may include multiple metallic pads 625 in contact with (e.g., coupled with) the insulative layer 615-b, where the metallic pads 625 may be coupled with an integrated circuit 630 (e.g., flip chip, semiconductor device).

In some examples, to alter the mechanical properties of the substrate 600, a mold material 620 may be patterned into the substrate 600, thereby countering the effects of material CTE mismatch, as described herein. For example, the hybrid layer 605 may include multiple portions of a first insulative material which alternate (e.g., in the x-direction) with portions 635 of the mold material 620, where the first insulative material may be a same material as those used for the insulative layers 615 (e.g., a first dielectric material). In such examples, the mold material 620 may be a second insulative material (e.g., second dielectric material) that is different from the insulative layers 615 and from the first insulative material. As illustrated, the hybrid layer 605 may include a first portion of the first insulative material, a portion 635a of the mold material 620, a second portion of the first insulative material, a portion 635b of the mold material 620, and a third portion of the first insulative material.

Similarly, the metallic layer 610-b and the insulative layer 615-b may include portions 635 of the mold material 620. For example, a portion 635-c of the mold material 620 may extend (e.g., in the z-direction) from the portion 635-a of the hybrid layer 605 through the metallic layer 610-b and the insulative layer 615-b to a top of the substrate 600, while a portion 635-d of the mold material 620 may also extend (e.g., in the z-direction) from the portion 635-b of the hybrid layer 605 through the metallic layer 610-b and the insulative layer 615-b to a top of the substrate 600. Additionally, as illustrated, the mold material 620 may also fill in gaps between each of the metallic pads 625, such that each metallic pad 625 is isolated from one another via a respective portion 635 of the mold material 620. Such portions 635 of the mold material 620 may provide altering CTE values within the substrate 600, thereby countering the effects of material CTE mismatch. That is, the mold material 620 may be deposited in areas of the substrate 600 associated with additional stress concentration (e.g., along an edge of a die, positions near the metallic pads 625), thereby alleviating the risk of potential failures due to mechanical stress.

To form the substrate 600, the insulative layer 615-a may be formed, where the metallic layer 610-a may be formed over the insulative layer 615-a. Based on forming the metallic layer 610-a, the hybrid layer 605 may be formed over the metallic layer 610-a. For example, the first insulative material of the hybrid layer 605 may be formed over the metallic layer 610-a, where multiple voids may be formed (e.g., patterned, etched) into the first insulative material of the hybrid layer 605. Alternatively, the first insulative material may be patterned with a sacrificial material, which may be removed in response to formation of the substrate 600 and prior to the deposition of the mold material 620, thereby exposing voids for the portions 635-a and 635-b of the mold material 620.

In response to forming the hybrid layer 605, the metallic layer 610-b may be formed over the hybrid layer 605 and the insulative layer 615-b may be formed over the metallic layer 610-b, where multiple voids may be formed (e.g., patterned, etched) through the insulative layer 615-b and through the metallic layer 610-b. Alternatively, the metallic layer 610-band the insulative layer 615-b may each be patterned with a sacrificial material, which may be removed in response to formation of the substrate 600 and prior to the deposition of the mold material 620, thereby exposing voids for the portions 635-c and 635-d of the mold material 620.

In response to forming the voids within the hybrid layer 605, the metallic layer 610-b, and the insulative layer 615-b, the metallic pads 625 may be formed over the insulative layer 615-b, where the integrated circuit 630 may be coupled with (e.g., soldered, connected to) the substrate 600 via the metallic pads 625. Accordingly, in such examples, the mold material 620 may be deposited between each of the metallic pads 625 to reduce mechanical stress, as described herein, where such mold material 620 may be vented through the voids and into the hybrid layer 605, thereby forming the portions 635. In addition to improving mechanical strength at the hybrid layer 605, such voids may be utilized as a vent for the mold material 620 (e.g., molding or other fill materials), which may reduce the risk of trapping voids within the materials of the substrates.

Accordingly, by implementing the portions 635 of the mold material 620 into the substrate 600 (e.g., the voided pattern), the substrate 600 may experience reduced mechanical stress, which may improve the durability and structural integrity of the substrate 600.

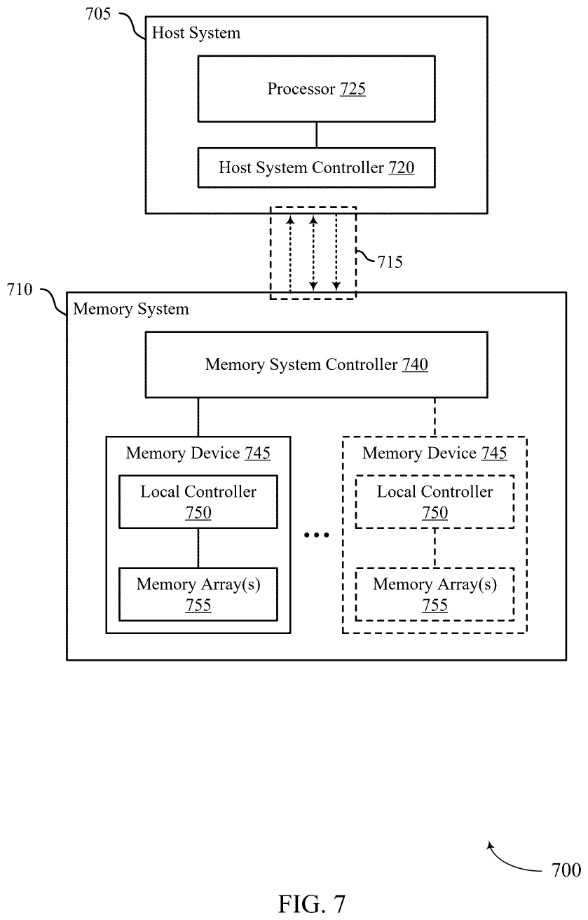

FIG. 7 shows an example of a system 700 that supports hybrid layers in substrates in accordance with examples as disclosed herein. The system 700 may include portions of an electronic device that, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 700 includes a host system 705, a memory system 710, and one or more channels 715 coupling the host system 705 with the memory system 710 (e.g., to support a communicative coupling). The system 700 may include any quantity of one or more memory systems 710 coupled with the host system 705.

In such examples, aspects of the system 700 may be coupled with the substrates 100, the substrate 200, the substrate 300, the substrate 400, the substrate 500, and the substrate 600, as described herein with reference to FIGS. 1 through 6. For example, a memory system 710 may be coupled with the various substrates (e.g., package substrates) as described herein, where the substrate and memory system 710 may be implemented within a host system 705. Alternatively, a host system 705 and a memory system 710 may be coupled (e.g., logic die to memory die), where either the host system 705 or the memory system 710 may be coupled with the substrates as described herein.

A host system 705 may include one or more components (e.g., circuitry, processing circuitry, application processing circuitry, one or more processing components) that use memory to execute processes (e.g., applications, functions, computations), any one or more of which may be referred to as or be included in a processor 725 (e.g., an application processor). A processor 725 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 725 may be an example of a central processing unit (CPU), a graphics processing unit (GPU), a general-purpose GPU (GPGPU), or an SoC or a component thereof, among other examples.

A host system 705 may also include at least one of one or more components (e.g., circuitry, logic, instructions) that implement the functions of an external memory controller (e.g., a host system memory controller), which may be referred to as or be included in a host system controller 720. For example, a host system controller 720 may issue commands or other signaling for operating a memory system 710, such as write commands, read commands, configuration signaling or other operational signaling. In some examples, a host system controller 720, or associated functions described herein, may be implemented by or be part of a processor 725. For example, a host system controller 720 may be hardware, instructions (e.g., software, firmware), or a combination thereof implemented by a processor 725 or other component of a host system 705. In various examples, a host system 705 or a host system controller 720 may be referred to as a host.

A memory system 710 provides physical memory locations (e.g., addresses) that may be used or referenced by the system 700. A memory system 710 may include a memory system controller 740 and one or more memory devices 745 (e.g., memory packages, memory dies, portions of a memory die) operable to store data. A memory system 710 may be configurable for operations with different types of host systems 705, and may respond to commands from the host system 705 (e.g., from a host system controller 720). For example, a memory system 710 (e.g., a memory system controller 740) may receive a write command indicating that the memory system 710 is to store data received from a host system 705, or receive a read command indicating that the memory system 710 is to provide data stored in a memory device 745 to a host system 705, or receive a refresh command indicating that the memory system 710 is to refresh data stored in a memory device 745, among other types of commands and operations.

A memory system controller 740 may include at least one of one or more components (e.g., circuitry, logic, instructions) operable to control operations of a memory system 710. A memory system controller 740 may include hardware or instructions that support the memory system 710 performing various operations, and may be operable to receive, transmit, or respond to commands, data, or control information related to operations of the memory system 710. A memory system controller 740 may be operable to communicate with one or more of a host system controller 720, one or more memory devices 745, or a processor 725. In some examples, a memory system controller 740 may control operations of the memory system 710 in cooperation with a host system controller 720, a local controller 750 of a memory device 745, or any combination thereof. Although the example of memory system controller 740 is illustrated as a separate component of the memory system 710, in some examples, aspects of the functionality of the memory system 710 may be implemented by a processor 725, a host system controller 720, at least one of one or more local controllers 750, or any combination thereof.

Each memory device 745 may include a local controller 750 (e.g., a logic controller, an interface controller, one or more processors) and one or more memory arrays 755. A memory array 755 may be a collection of memory cells (e.g., a two-dimensional array, a three-dimensional array, an array of one or more semiconductor components), with each memory cell being operable to store data (e.g., as one or more stored bits). Each memory array 755 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 750 may include at least one of one or more components (e.g., circuitry, logic, instructions) operable to control operations of a memory device 745. In some examples, a local controller 750 may be operable to communicate (e.g., receive or transmit data or commands or both) with a memory system controller 740. In some examples, a memory system 710 may not include a memory system controller 740, and a local controller 750 or a host system controller 720 may perform functions of a memory system controller 740 described herein. In some examples, a local controller 750, or a memory system controller 740, or both may include decoding components operable for accessing addresses of a memory array 755, sense components for sensing states of memory cells of a memory array 755, write components for writing states to memory cells of a memory array 755, or various other components operable for supporting described operations of a memory system 710.

A host system 705 (e.g., a host system controller 720) and a memory system 710 (e.g., a memory system controller 740) may communicate information (e.g., data, commands, control information, configuration information, timing information) using one or more channels 715. Each channel 715 may be an example of a transmission medium that carries information, and each channel 715 may include one or more signal paths (e.g., a transmission medium, an electrical conductor, a conductive path) between terminals (e.g., nodes, pins, contacts) associated with the components of the system 700. A terminal may be an example of a conductive input or output point of a device of the system 700, and a terminal may be operable as part of a channel 715. In some implementations, at least the channels 715 between a host system 705 and a memory system 710 may include or be referred to as a host interface (e.g., a physical host interface). To support communications over channels 715, a host system 705 (e.g., a host system controller 720) and a memory system 710 (e.g., a memory system controller 740) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 715, which may be included in a respective interface portion of the respective system.

A channel 715 may be dedicated to communicating one or more types of information, and channels 715 may include unidirectional channels, bidirectional channels, or both. For example, the channels 715 may include one or more command/address channels, one or more clock signal channels, one or more data channels, among other channels or combinations thereof. In some examples, a channel 715 may be configured to provide power from one system to another (e.g., from the host system 705 to the memory system 710, in accordance with a regulated voltage). In some examples, at least a subset of channels 715 may be configured in accordance with a protocol (e.g., a logical protocol, a communications protocol, an operational protocol, an industry standard), which may support configured operations of and interactions between a host system 705 and a memory system 710.

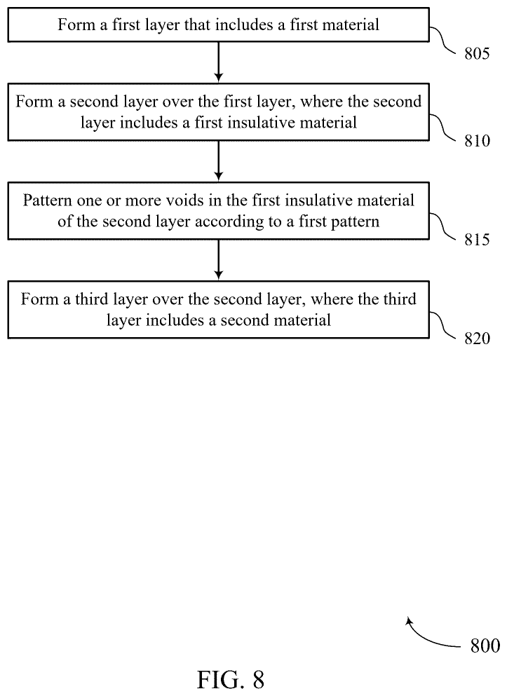

FIG. 8 shows a flowchart illustrating a method 800 that supports hybrid layers in substrates in accordance with examples as disclosed herein. The operations of method 800 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 805, the method 800 may include forming a first layer that includes a first material. At 810, the method 800 may include forming a second layer over the first layer, where the second layer includes a first insulative material. At 815, the method 800 may include patterning one or more voids in the first insulative material of the second layer according to a first pattern. At 820, the method 800 may include forming a third layer over the second layer, where the third layer includes a second material.

In some examples, an apparatus (e.g., a manufacturing system) as described herein may perform a method or methods, such as the method 800. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a first layer that includes a first material; forming a second layer over the first layer, where the second layer includes a first insulative material; patterning one or more voids in the first insulative material of the second layer according to a first pattern; and forming a third layer over the second layer, where the third layer includes a second material.

Aspect 2: The method or apparatus of aspect 1, where patterning the one or more voids includes operations, features, circuitry, logic, means, or instructions, or any combination thereof for etching the one or more voids into the first insulative material according to the first pattern based at least in part on forming the first insulative material, where etching the one or more voids is performed according to a dry etching procedure, a wet etching procedure, a laser drilling procedure, a machining procedure, or any combination thereof.

Aspect 3: The method or apparatus of any of aspects 1 through 2, where patterning the one or more voids includes operations, features, circuitry, logic, means, or instructions, or any combination thereof for combining the first insulative material with a sacrificial material according to the first pattern and removing the sacrificial material from the first insulative material to form the one or more voids, where the sacrificial material is removed according to a chemical removal process, according to a saturation process, according to a reflow process that occurs after forming the third layer over the second layer, or any combination thereof.

Aspect 4: method or apparatus of any of aspects 1 through 3, further including operations, features, circuitry, logic, means, or instructions, or any combination thereof for depositing a third material into each void of the one or more voids, where forming the third layer is based at least in part on depositing the first material, and where the third material includes a thermally conductive material, a metal material, a dielectric material, or any combination thereof.

Aspect 5: The method or apparatus of any of aspects 1 through 4, further including operations, features, circuitry, logic, means, or instructions, or any combination thereof for forming a plurality of metallic pads over the third layer based at least in part on forming the third layer and coupling an integrated circuit to each metallic pad of the plurality of metallic pads.

Aspect 6: The method or apparatus of any of aspects 1 through 5, where the first material includes a second insulative material, a first metal material, or any combination of both and the second material includes a third insulative material, a second metal material, or any combination of both.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 7: A substrate, including: a first layer including a first metal material; a hybrid layer positioned over the first layer in a first direction and extending along the first layer in a second direction that is perpendicular to the first direction, where the hybrid layer includes a first insulative material patterned with one or more portions of a first material, the first material including a second metal material or a second insulative material; and a second layer positioned over the hybrid layer in the first direction and extending along the hybrid layer in the second direction, the second layer including a third metal material.

Aspect 8: The substrate of aspect 7, where: the first layer includes a first metallic plane and a first metallic signal path, the second layer includes a second metallic signal path, a third metallic signal path, and a third metallic plane positioned, in the second direction between the second metallic signal path and the third metallic signal path, and the hybrid layer includes a first portion of the one or more portions of the first material that couples the first metallic plane with the third metallic plane and includes a second portion of the one or more portions of the first material that couples the first metallic signal path with the second metallic signal path.

Aspect 9: The substrate of aspect 8, where the first material includes the second metal material, and the second metal material includes copper.

Aspect 10: The substrate of any of aspects 7 through 9, where the hybrid layer includes: a first portion of the one or more portions of the first material at first end of the substrate, where the first portion extends, in the second direction, from the first end of the substrate into a first length of the first insulative material, and where the first portion extends, in the first direction, from the second layer into a second length of the first insulative material; and a second portion of the one or more portions of the first material at a second end of the substrate, where the second portion extends, in the second direction, from the second end of the substrate into a third length of the first insulative material, and where the second portion extends, in the first direction, from the second layer into a fourth length of the first insulative material.

Aspect 11: The substrate of aspect 10, where the first material includes a thermally conductive material, and a thermal conductivity of the first insulative material is less than the thermal conductivity of the thermally conductive material.

Aspect 12: The substrate of any of aspects 7 through 11, where the hybrid layer further includes: a plurality of portions of the first insulative material, where the one or more portions of the first material alternate, along the second direction of the hybrid layer, with the plurality of portions of the first insulative material.

Aspect 13: The substrate of aspect 12, where the substrate further includes: a third layer positioned over the second layer in the first direction and extending along the second layer in the second direction, where the third layer includes a third first insulative material; and one or more second portions of the first material, where each second portion of the one or more second portions extends, in the first direction, from a respective portion of the one or more portions of the first material through the second layer of the substrate and through the third layer of the substrate.

Aspect 14: The substrate of aspect 13, where the substrate further includes: a plurality of metallic pads over the third layer in the first direction and distributed over the third layer along the second direction; an integrated circuit coupled with each of the plurality of metallic pads; and one or more third portions of the first material positioned between each metallic pad of the plurality of metallic pads and between a top of the third layer and a bottom of the integrated circuit.

Aspect 15: The substrate of any of aspects 13 through 14, where the first material includes the second insulative material.

Aspect 16: The substrate of any of aspects 7 through 15, where the substrate further includes: a third layer positioned over the second layer in the first direction and extending along the second layer in the second direction, where the third layer includes a third insulative material; a plurality of metallic pads over the third layer in the first direction and distributed over the third layer along the second direction; and an integrated circuit coupled with each of the plurality of metallic pads.

An apparatus is described. The following provides an overview of aspects of the apparatus as described herein:

Aspect 17: A substrate, including: a plurality of metallic layers; a plurality of insulative layers, where each insulative layer of the plurality of insulative layers is positioned, in a first direction, between respective metallic layers of the plurality of metallic layers, and where each insulative layer of the plurality of insulative layers extends, in a second direction perpendicular to the first direction, along the respective metallic layers of the plurality of metallic layers; and one or more voids formed within a first insulative layer of the plurality of insulative layers according to a first pattern.

Aspect 18: The substrate of aspect 17, where the substrate further includes: one or more second voids, where each second void of the one or more second voids extends, in the first direction, from a respective void of the one or more voids through a subset of the plurality of metallic layers and through a subset of the plurality of insulative layers.

Aspect 19: The substrate of any of aspects 17 through 18, where the first insulative layer includes: a first void of the one or more voids at a first end of the substrate, where the first void extends, in the second direction, from the first end of the substrate into a first length of the first insulative layer, and where the first void extends, in the first direction, from a top of the first insulative layer into a second length of the first insulative layer; and a second void of the one or more voids at a second end of the substrate opposite the first end, where the second void extends, in the second direction, from the second end of the substrate into a third length of the first insulative layer, and where the second void extends, in the first direction, from the top of the first insulative layer into a fourth length of the first insulative layer.

Aspect 20: The substrate of aspect 19, where the first insulative layer includes one of a sintered porous plastic, a porous fiber, a polytetrafluoroethylene membrane, hollow glass strands, a soluble resin material, or any combination thereof.

Aspect 21: The substrate of any of aspects 17 through 20, where the first insulative layer includes: a first void of the one or more voids at a first end of the substrate, where the first void extends, in the second direction, from the first end of the substrate into a first length of the first insulative layer, and where the first void extends, in the first direction, from a top of the first insulative layer into a second length of the first insulative layer; and a second void of the one or more voids that extends, in the first direction, from the first void through a subset of the plurality of metallic layers and through a subset of the plurality of insulative layers.

Aspect 22: The substrate of aspect 21, where the substrate further includes: a second insulative layer positioned, in the first direction, over the plurality of metallic layers and the plurality of insulative layers; a first set of metallic pads over the second insulative layer in the first direction, and where the first set of metallic pads is distributed over the second insulative layer along the second direction from a first side of the second void; a second set of metallic pads over the second insulative layer in the first direction, and where the second set of metallic pads is distributed over the second insulative layer along the second direction from a second side of the second void opposite the first side; and an integrated circuit coupled with each of metallic pad of the first set of metallic pads and the second set of metallic pads, where the first void and the second void form a convective vent to facilitate a flow of air from the integrated circuit, to the integrated circuit, or both.

Aspect 23: The substrate of any of aspects 17 through 22, where the substrate further includes: a second insulative layer positioned, in the first direction, over the plurality of metallic layers and the plurality of insulative layers; a plurality of metallic pads over the second insulative layer in the first direction and distributed over the second insulative layer along the second direction; and a memory device coupled with each of the plurality of metallic pads.

Aspect 24: The substrate of any of aspects 17 through 23, where each of the plurality of metallic layers include a copper, and each insulative layer of the plurality of insulative layers includes a dielectric material.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A substrate, comprising:
a first layer comprising a first metal material;
a hybrid layer positioned over the first layer in a first direction and extending along the first layer in a second direction that is perpendicular to the first direction, wherein the hybrid layer comprises a first insulative material patterned with one or more portions of a first material, the first material comprising a second metal material or a second insulative material; and
a second layer positioned over the hybrid layer in the first direction and extending along the hybrid layer in the second direction, the second layer comprising a third metal material.

2. The substrate of claim 1, wherein:
the first layer comprises a first metallic plane and a first metallic signal path,
the second layer comprises a second metallic signal path, a third metallic signal path, and a third metallic plane positioned, in the second direction between the second metallic signal path and the third metallic signal path, and
the hybrid layer comprises a first portion of the one or more portions of the first material that couples the first metallic plane with the third metallic plane and comprises a second portion of the one or more portions of the first material that couples the first metallic signal path with the second metallic signal path.

3. The substrate of claim 2, wherein:
the first material comprises the second metal material, and the second metal material comprises copper.

4. The substrate of claim 1, wherein the hybrid layer comprises:
a first portion of the one or more portions of the first material at first end of the substrate, wherein the first portion extends, in the second direction, from the first end of the substrate into a first length of the first insulative material, and wherein the first portion extends, in the first direction, from the second layer into a second length of the first insulative material; and
a second portion of the one or more portions of the first material at a second end of the substrate, wherein the second portion extends, in the second direction, from the second end of the substrate into a third length of the first insulative material, and wherein the second portion extends, in the first direction, from the second layer into a fourth length of the first insulative material.

5. The substrate of claim 4, wherein:
the first material comprises a thermally conductive material, and
a thermal conductivity of the first insulative material is less than the thermal conductivity of the thermally conductive material.

6. The substrate of claim 1, wherein the hybrid layer further comprises:
a plurality of portions of the first insulative material, wherein the one or more portions of the first material alternate, along the second direction of the hybrid layer, with the plurality of portions of the first insulative material.

7. The substrate of claim 6, wherein the substrate further comprises:
a third layer positioned over the second layer in the first direction and extending along the second layer in the second direction, wherein the third layer comprises a third first insulative material; and
one or more second portions of the first material, wherein each second portion of the one or more second portions extends, in the first direction, from a respective portion of the one or more portions of the first material through the second layer of the substrate and through the third layer of the substrate.

8. The substrate of claim 7, wherein the substrate further comprises:
a plurality of metallic pads over the third layer in the first direction and distributed over the third layer along the second direction;
an integrated circuit coupled with each of the plurality of metallic pads; and
one or more third portions of the first material positioned between each metallic pad of the plurality of metallic pads and between a top of the third layer and a bottom of the integrated circuit.

9. The substrate of claim 7, wherein the first material comprises the second insulative material.

10. The substrate of claim 1, wherein the substrate further comprises:
a third layer positioned over the second layer in the first direction and extending along the second layer in the second direction, wherein the third layer comprises a third insulative material;
a plurality of metallic pads over the third layer in the first direction and distributed over the third layer along the second direction; and
an integrated circuit coupled with each of the plurality of metallic pads.

11. A substrate, comprising:
a plurality of metallic layers;
a plurality of insulative layers, wherein each insulative layer of the plurality of insulative layers is positioned, in a first direction, between respective metallic layers of the plurality of metallic layers, and wherein each insulative layer of the plurality of insulative layers extends, in a second direction perpendicular to the first direction, along the respective metallic layers of the plurality of metallic layers; and
one or more voids formed within a first insulative layer of the plurality of insulative layers according to a first pattern.

12. The substrate of claim 11, wherein the substrate further comprises:
one or more second voids, wherein each second void of the one or more second voids extends, in the first direction, from a respective void of the one or more voids through a subset of the plurality of metallic layers and through a subset of the plurality of insulative layers.

13. The substrate of claim 11, wherein the first insulative layer comprises:
a first void of the one or more voids at a first end of the substrate, wherein the first void extends, in the second direction, from the first end of the substrate into a first length of the first insulative layer, and wherein the first void extends, in the first direction, from a top of the first insulative layer into a second length of the first insulative layer; and
a second void of the one or more voids at a second end of the substrate opposite the first end, wherein the second void extends, in the second direction, from the second end of the substrate into a third length of the first insulative layer, and wherein the second void extends, in the first direction, from the top of the first insulative layer into a fourth length of the first insulative layer.

14. The substrate of claim 13, wherein the first insulative layer comprises one of a sintered porous plastic, a porous fiber, a polytetrafluoroethylene membrane, hollow glass strands, a soluble resin material, or any combination thereof.

15. The substrate of claim 11, wherein the first insulative layer comprises:
a first void of the one or more voids at a first end of the substrate, wherein the first void extends, in the second direction, from the first end of the substrate into a first length of the first insulative layer, and wherein the first void extends, in the first direction, from a top of the first insulative layer into a second length of the first insulative layer; and
a second void of the one or more voids that extends, in the first direction, from the first void through a subset of the plurality of metallic layers and through a subset of the plurality of insulative layers.

16. The substrate of claim 15, wherein the substrate further comprises:
a second insulative layer positioned, in the first direction, over the plurality of metallic layers and the plurality of insulative layers;
a first set of metallic pads over the second insulative layer in the first direction, and wherein the first set of metallic pads is distributed over the second insulative layer along the second direction from a first side of the second void;
a second set of metallic pads over the second insulative layer in the first direction, and wherein the second set of metallic pads is distributed over the second insulative layer along the second direction from a second side of the second void opposite the first side; and
an integrated circuit coupled with each of metallic pad of the first set of metallic pads and the second set of metallic pads, wherein the first void and the second void form a convective vent to facilitate a flow of air from the integrated circuit, to the integrated circuit, or both.

17. The substrate of claim 11, wherein the substrate further comprises:
a second insulative layer positioned, in the first direction, over the plurality of metallic layers and the plurality of insulative layers;
a plurality of metallic pads over the second insulative layer in the first direction and distributed over the second insulative layer along the second direction; and
a memory device coupled with each of the plurality of metallic pads.

18. The substrate of claim 11, wherein:
each of the plurality of metallic layers comprise a copper, and
each insulative layer of the plurality of insulative layers comprises a dielectric material.

19. A method of forming a substrate, comprising:
forming a first layer that comprises a first material;
forming a second layer over the first layer, wherein the second layer comprises a first insulative material;
patterning one or more voids in the first insulative material of the second layer according to a first pattern; and
forming a third layer over the second layer, wherein the third layer comprises a second material.

20. The method of claim 19, wherein patterning the one or more voids comprises:
etching the one or more voids into the first insulative material according to the first pattern based at least in part on forming the first insulative material, wherein etching the one or more voids is performed according to a dry etching procedure, a wet etching procedure, a laser drilling procedure, a machining procedure, or any combination thereof.

21. The method of claim 19, wherein patterning the one or more voids comprises:
combining the first insulative material with a sacrificial material according to the first pattern; and
removing the sacrificial material from the first insulative material to form the one or more voids, wherein the sacrificial material is removed according to a chemical removal process, according to a saturation process, according to a reflow process that occurs after forming the third layer over the second layer, or any combination thereof.

22. The method of claim 19, further comprising:
depositing a third material into each void of the one or more voids, wherein forming the third layer is based at least in part on depositing the first material, and wherein the third material comprises a thermally conductive material, a metal material, a dielectric material, or any combination thereof.

23. The method of claim 19, further comprising:
forming a plurality of metallic pads over the third layer based at least in part on forming the third layer; and
coupling an integrated circuit to each metallic pad of the plurality of metallic pads.

24. The method of claim 19, wherein:
the first material comprises a second insulative material, a first metal material, or any combination of both, and
the second material comprises a third insulative material, a second metal material, or any combination of both.
